(19) United States
(12) Patent Application Publication
(10) Pub. No.: US 2025/0017006 A1
(43) Pub. Date: Jan. 9, 2025

(54) THREE-DIMENSIONAL MEMORY DEVICE UTILIZING DUMMY MEMORY BLOCKS TO MITIGATE DEFECTS

(71) Applicant: Yangtze Memory Technologies Co., Ltd., Wuhan (CN)

(72) Inventors: Fan Gong, Wuhan (CN); Simin Liu, Wuhan (CN); Bin Yuan, Wuhan (CN); Bo Xu, Wuhan (CN); Wei Xu, Wuhan (CN); Lei Xue, Wuhan (CN); Zongliang Huo, Wuhan (CN)

(21) Appl. No.: 18/233,923

(22) Filed: Aug. 15, 2023

Related U.S. Application Data
(63) Continuation of application No. PCT/CN2023/105829, filed on Jul. 5, 2023.

(51) Int. Cl. H10B 43/27; H01L 23/00

(52) U.S. Cl. CPC H10B 43/27; H01L 23/562

(57) ABSTRACT

Structures of a three-dimensional (3D) memory device and systems containing the same are disclosed. In one example, the 3D memory device includes a memory plane, where the memory plane includes a first edge and an array of blocks. The array of blocks includes a plurality of memory blocks configured to store data, where the plurality of memory blocks are separated by continuous slit structures, and a first dummy region between the first edge and the plurality of memory blocks. The first dummy region includes alternating first slit structures and second slit structures, where the first slit structures and the second slit structures are discontinuous slit structures.

### CROSS-REFERENCE TO RELATED APPLICATIONS

This application is a continuation of International Application No. PCT/CN2023/105829, filed on Jul. 5, 2023, the disclosure of which is hereby incorporated by reference in its entirety.

### TECHNICAL FIELD

This specification relates to the field of semiconductor technology, more particularly, to a three-dimensional (3D) memory device (e.g., a 3D NAND memory device) utilizing one or more dummy memory blocks to mitigate defects.

### BACKGROUND

As memory devices continually shrink to reduce manufacturing costs and increase storage density, scaling of planar memory cells faces challenges due to process technology limitations and reliability issues. A three-dimensional (3D) memory architecture can address the density and performance limitations of planar memory cells.

Planar memory cells have scaled to smaller sizes by improving process technology, circuit design, programming algorithms, and fabrication processes. However, as feature sizes of the memory cells approach a lower limit, planar processes and fabrication techniques become challenging and costly. As a result, memory density for planar memory cells approaches an upper limit. 3D memory architecture can address the density limitations in planar memory cells by stacking memory cells vertically in a memory block. 3D architecture generally includes multiple arrays of memory blocks and peripheral devices (e.g., a memory controller) for controlling data requests to and from the memory blocks in the arrays.

Nevertheless, 3D memory architecture is rapidly approaching an upper limit on the height of functional memory blocks due to structural instabilities. As the height grows, instabilities (e.g., due to various stresses) in the 3D architecture can cause numerous memory blocks to fail, thereby reducing the memory capacity of the 3D architecture and potentially rendering the 3D architecture inoperative. The gains achieved by 3D architectures over planar memory cells can be significantly diminished by the failure of one or more memory blocks, leading to a tradeoff between memory density and number of memory blocks in an array.

### SUMMARY

This specification describes a three-dimensional (3D) memory device (e.g., a 3D NAND memory device) utilizing one or more dummy memory blocks to mitigate defects and improve structural stability. Systems containing the 3D memory device are also described.

In one aspect, a 3D memory device includes a memory plane, where the memory plane includes a first edge and an array of blocks. The array of blocks includes a plurality of memory blocks configured to store data, where the plurality of memory blocks are separated by continuous slit structures, and a first dummy region between the first edge and the plurality of memory blocks. The first dummy region includes alternating first slit structures and second slit structures, where the first slit structures and the second slit structures are discontinuous slit structures.

In another aspect, a system includes a 3D memory device and a memory controller electrically connected to the 3D memory device, where the memory controller is configured to manage data to and from the 3D memory device. The 3D memory device includes a memory plane, where the memory plane includes a first edge and an array of blocks. The array of blocks includes a plurality of memory blocks configured to store data, where the plurality of memory blocks are separated by continuous slit structures, and a first dummy region between the first edge and the plurality of memory blocks. The first dummy region includes alternating first slit structures and second slit structures, where the first slit structures and the second slit structures are discontinuous slit structures.

In yet another aspect, a 3D memory device includes a memory plane, where the memory plane includes a first edge and an array of blocks. The array of blocks includes a plurality of memory blocks configured to store data, where the plurality of memory blocks are separated by continuous slit structures, and one or more dummy blocks between the first edge and the plurality of memory blocks. Each dummy block includes a first slit structure separating adjacent blocks and one or more second slit structures dividing the dummy block into a plurality of fingers, where the first slit structure and the one or more second slit structures are discontinuous slit structures.

Particular embodiments of the subject matter described in this specification can be implemented so as to realize one or more of the following advantages.

The present disclosure introduces 3D memory architectures that achieve improved structural stability and mitigation of defects without sacrificing a significant number of memory blocks. In particular, the 3D architectures utilize one or more dummy memory blocks fabricated at the edges of an array to stabilize the functional memory blocks in the array. By intentionally using appropriately fabricated dummy blocks, the functional memory blocks can exhibit reduced stress and are less prone to defects. The number of functional memory blocks in an array can be increased, therefore increasing storage density and overall data storage capacity. Moreover, due to stabilization from the dummy blocks, the height of the memory blocks can also be increased to provide further gains in storage capacity. The devices and techniques for stabilizing 3D memory architectures provided in this disclosure improve memory capacity, reduce device defects, and increase fabrication yield of such devices.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is an isometric view depicting an example of a three-dimensional (3D) memory block.

FIG. 2A is a top view depicting an example of a 3D memory structure.

FIGS. 2B-2D are cross-sectional views depicting the 3D memory structure of FIG. 2A.

FIGS. 3A and 3B are top views depicting examples of two 3D memory structures forming a 3D memory block.

FIG. 4 is a top view depicting an example of a semiconductor die supporting multiple 3D memory devices.

FIG. 5 is a top view depicting an example of a 3D memory device supporting multiple memory planes.

FIG. 6A is a top view depicting an example of a defective memory plane including an array of memory blocks.

FIG. 6B is a top view depicting an example of a defective memory block included in the defective memory plane of FIG. 6A.

FIG. 6C is a top view depicting an example of a defective slit structure (SS) in the defective memory block of FIG. 6B.

FIG. 7A is a top view depicting an example a of memory plane including an array of memory blocks and a dummy region.

FIG. 7B is a top view depicting an example of a memory block included in the memory plane of FIG. 7A.

FIG. 7C is a top view depicting an example of a SS in the memory block of FIG. 7B.

FIGS. 8A-8C are top views depicting examples of dummy regions including one or more dummy memory blocks.

FIGS. 9A and 9B are top views depicting examples of a memory block and a dummy region with a core array region between two staircase structure regions.

FIG. 10 is a schematic diagram depicting an example system including one or more 3D memory devices and a memory controller.

Like reference numbers and designations in the various drawings indicate like elements.

### DETAILED DESCRIPTION

References will now be made in detail to example embodiments, which are illustrated in the accompanying drawings in order to understand and implement the present disclosure, and to realize the technical effect. It can be understood that the following description has been made only by way of example, but not to limit the present disclosure. Various embodiments of the present disclosure and various features in the embodiments that do not conflict with each other can be combined and rearranged in various ways. Without departing from the spirit and scope of the present disclosure, modifications, equivalents, or improvements to the present disclosure are understandable to those of ordinary skill in the art and are intended to be encompassed within the scope of the present disclosure.

It is noted that references in the specification to “one embodiment”, “an embodiment”, “an exemplary embodiment”, “some embodiments”, etc., indicate that the embodiment described may include a particular feature, structure, or characteristic, but every embodiment may not necessarily include the particular feature, structure, or characteristic. Moreover, such phrases do not necessarily refer to the same embodiment.

Further, when a particular feature, structure or characteristic is described in contact with an embodiment, it would be within the knowledge of a person of ordinary skill in the pertinent art to affect such feature, structure or characteristic in contact with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a”, “an”, or “the”, again, may be understood to convey a singular usage or to convey a plural usage, depending at least in part upon context.

It should be readily understood that the meaning of “on”, “above”, and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath”, “below”, “lower”, “above”, “upper”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. The term “vertical” refers to the direction perpendicular to the surface of a semiconductor substrate, and the term “horizontal” refers to any direction that is parallel to the surface of that semiconductor substrate.

As used herein, the term “substrate” generally refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, an oxide, or a sapphire wafer.

As used herein, the term “layer” generally refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical contacts are formed) and one or more dielectric layers.

As used herein, the term “3D memory device” generally refers to a semiconductor device with vertically oriented strings of memory cell transistors (referred to herein as “memory strings,” such as NAND strings) on a laterally-oriented substrate so that the memory strings extend in the vertical direction with respect to the substrate. As used herein, the term “vertical” or “vertically” generally means a direction perpendicular to the lateral surface of the substrate.

As used herein, the term “tier” generally refers to elements of substantially the same height along the vertical direction. For example, a word line (e.g., a control gate electrode) and an underlying gate dielectric layer can together be referred to as a tier. A sacrificial layer and an underlying insulating layer can together be referred to as a tier. A conductive layer and an underlying insulating layer can together be referred to as a tier. Word lines of substantially the same height can be referred to as a tier of word lines or similar, and so on.

As used herein, the term “slit structure” generally refers to a feature that traverses through the stacked layers of a 3D memory device in the vertical direction and is substantially linear in the horizontal. An illustrative analogy is a cut through a layered cake. The slit structure may or may not traverse through the underlying substrate of the 3D memory device. In some implementations, a slit structure may be referred to as a “gate line slit” or “gate line slit structure”. For example, a slit structure can separate and electrically isolate different gate electrodes (or word lines) of the same tier on either side of the slit structure. A slit structure can be continuous (a “continuous slit structure”) such that the slit structure is uninterrupted along its length in the horizontal (e.g., resembling a solid line from a top-down perspective). A slit structure can also be discontinuous (a “discontinuous slit structure”) such that the slit structure is interrupted along its length in the horizontal (e.g., resembling a dashed line from a top-down perspective).

Some 3D memory devices (e.g., 3D NAND memory devices) include multiple memory planes where each plane accommodates a certain data storage capacity. A memory plane generally includes a series of 3D memory blocks arranged in a linear array for storing data. A 3D memory block stacks memory cells vertically (in the form of memory strings) to increase storage density and lower cost per gigabyte. Memory cells are usually embedded in a stack of word lines (e.g., control gate electrodes) and semiconductor channels formed vertically through the stack. That is, the intersection of a word line and a semiconductor channel forms a memory cell transistor. Multiple intersections of stacked word lines with a semiconductor channel forms a memory string. 3D memory blocks usually include staircase structures formed on one or more sides, or at the center, of the stacked data storage structure for purposes such as word line pick-up and fan-out using metal contact vias landed onto different tiers (or steps) of a staircase structure.

Continuous slit structures (SSs) are often formed between adjacent memory blocks to separate and electrically isolate memory blocks from one another in an array. Discontinuous SSs can also be formed within a memory block itself to divide the memory block into multiple fingers. Each finger may be associated with a subset of memory strings of the memory block to provide improved data communications with individual memory cells in the strings. The discontinuous SSs between fingers can allow some portions of adjacent fingers to be electrically isolated from each other while other portions are electrically connected. This feature can reduce the number of metal contact vias involved in word line pick-up, as well as the probability of connection failures.

However, as the staircase structure grows with increasing layers of stacked memory cells, instabilities in a memory block (e.g., due stresses at the edges of a memory plane) can cause distortions and/or variations in the SSs (both continuous and discontinuous SSs). These distortions may render multiple memory blocks in a memory plane inoperable, thereby reducing data storage capacity. The number of defects and inoperable memory blocks can be unpredictable and may be large enough that the entire 3D memory device is discarded which reduces fabrication yield.

To address one or more of these aforementioned issues, the present disclosure introduces a solution that achieves structural stability in 3D memory architectures without sacrificing a significant number of memory blocks. In particular, the present disclosure utilizes one or more dummy memory blocks fabricated at the edges of a memory plane to stabilize the functional memory blocks. By intentionally using dummy blocks fabricated with appropriate SSs, the functional memory blocks can exhibit reduced stress and are less prone to defects. The number of functional memory blocks in an array, as well as the height of the memory blocks, can be increased, thereby increasing storage density and overall data storage capacity.

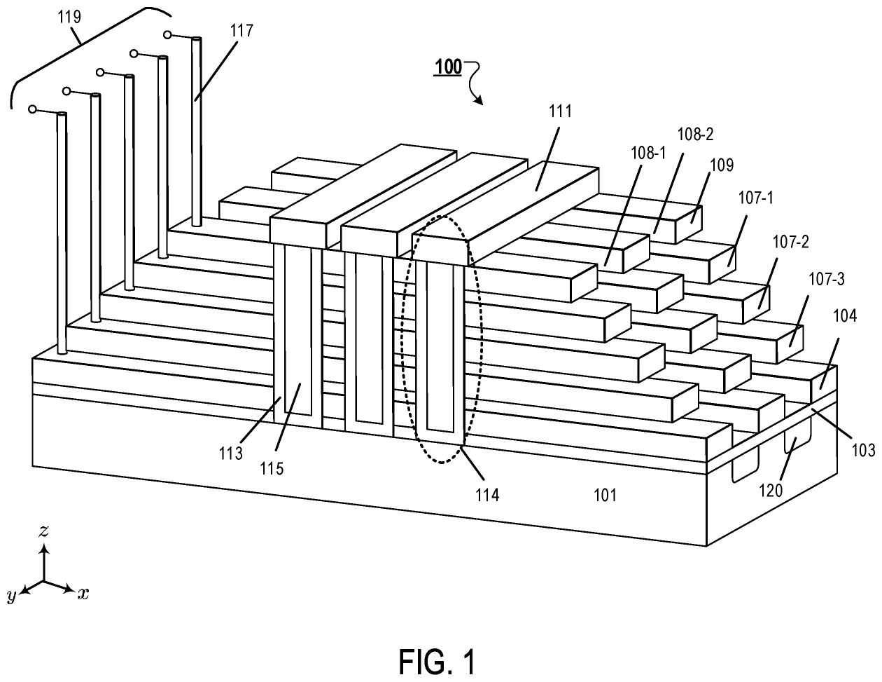

FIG. 1 shows an example of a three-dimensional (3D) memory block 100 configured to store data. Specifically, the memory block 100 utilizes an array of memory strings 114 each composed of a stack of memory cells. The memory cells store bits of data in the form of trapped electric charge. A memory block can store data and communicate with various peripheral devices, such as a memory controller, in order to execute read and/or write requests to individual memory cells. As will be described in the following, multiple memory blocks can be integrated onto a single memory plane, e.g., in a linear array, to accommodate a desired data storage capacity. The memory plane can also include one or more appropriately fabricated dummy blocks to stabilize the array and reduce the prevalence of defects in the memory blocks. The memory block 100 of FIG. 1 is an example of a NAND flash memory block. However, the 3D memory architectures discussed herein are not limited to such and can incorporate various types of 3D memory blocks, e.g., 3D NOR flash memory blocks, 3D RRAM memory blocks, etc.

The 3D memory block 100 includes a substrate 101 that supports several stacked layers of components. The substrate 101 also includes doped source line regions 120 that form a well structure for the memory block 100. The substrate 101 is covered by an insulating layer 103 to electrically isolate the substrate 101 from the other layers. Multiple tiers of gate electrodes 104, 107, and 109 are stacked in the vertical (z) direction on top of the insulating layer 103 and extend in the horizontal (x) direction. Although not shown in FIG. 1, each tier of gate electrodes generally includes an insulating layer (and/or a gate dielectric layer) to electrically isolate gate electrodes of different tiers. In this example implementation, the tiers of gate electrodes form two staircase structures on opposing sides of the memory block 100. The staircase structures correspond to ascending tiers (or steps) from the opposing sides of the memory block 100 toward its center. Bit lines 111 are arranged orthogonally to the gate electrodes (in the y direction) on the topmost tier of the memory block 100.

A tier of lower selective gate electrodes 104 resides on top of the insulating layer 103. The lower gate electrodes 104 function as the source select gates for the memory block 100. The source line regions 120 are positioned in the substrate 101 between adjacent lower selective gate electrodes 104. Multiple tiers of control gate electrodes 107-1, 107-2, and 107-3 are stacked sequentially over the lower selective gate electrodes 104 and function as the word lines of the memory block 100. A tier of upper selective gate electrodes 109 resides on top of the control gate electrodes 107. The upper gate electrodes 109 function as the drain select gates for the memory block 100. A gate electrode of each tier is electrically connected to a metal interconnect 119 through a metal contact via 117 landed on each tier for word line pick-up, e.g., to communicate with peripheral devices.

Adjacent gate electrodes 104, 107, and 109 in each tier are separated by parallel slit structures (SSs) 108-1 and 108-2. The SSs 108 traverse vertically through the stack of gate electrodes in order to separate adjacent gate electrodes into distinct electrically conducting pathways. Although not shown in FIG. 1, the SSs 108 are generally lined and/or filled with one or more materials to electrically isolate gate electrodes of the same tier. In some implementations, the SSs 108 also interact with the source lines 120. For instance, the SSs 108 can be lined with an insulating material to electrically insulate adjacent gate electrodes from one another. The lined SSs 108 can be filled with a conductive material (e.g., a metal or a semiconductor) to form a metal-insulator-semiconductor (MIS) capacitor interface between the conductive material, insulating layer 103 and doped source line regions 120. The MIS capacitor can be biased with a voltage to alter the conduction properties in the substrate 101, for example, to generate a depletion layer and/or an inversion layer in the source line regions 120 between the lower gate electrodes 104.

Multiple semiconductor channels 114 traverse vertically through the stacked tiers of gate electrodes 104, 107, and 109 in the center of the memory block 100. The semiconductor channels 114 are electrically connected to the bit lines 111 residing on the topmost tier. The intersection of a semiconductor channel 114 and a control gate electrode (word line) 107 corresponds to an individual memory cell transistor, e.g., a field effect transistor. Hence, each semiconductor channel 114 functions as a memory string. The collection of semiconductor channels 114 constitutes the stacked data storage structure of the memory block 100.

The memory cells can receive read and/or write requests by the bit lines 111 and the control gate electrodes 107. In particular, rows of memory cells in the y direction can be accessed by the bit lines 111 and rows of memory cells in the x direction can be accessed by the control gate electrodes 107. Control gate electrodes of different tiers, 107-1, 107-2, and 107-3, can access different memory cells in the z direction. The lower and upper gate electrodes, 104 and 109, can facilitate read out of the memory cells. Accordingly, any individual memory cell can be read and/or programmed by appropriately modulated bit lines 111 and gate electrodes 104, 107 and 109. For example, when a specified voltage is placed on a bit line 111 and/or a control gate electrode 107, the presence or absence of stored charge in a memory cell, corresponding to a bit of data, results in a change in electrical impedance through a respective semiconductor channel 114. The change in impedance will either allow or inhibit current flow through the semiconductor channel 114 which can be sensed by a source select gate 104 and a drain select gate 107 to determine the programmed state of the memory cell.

The semiconductor channels 114 are lined with a memory layer 113 to store charge (e.g., bits of data) and can be partially or fully filled with a dielectric filler such as silicon dioxide. Semiconductor channels 114 can also support various other layers. For instance, a semiconducting layer (e.g., a channel layer) can be situated between the memory layer 113 and the dielectric filler 115 to facilitate current flow within the semiconductor channels 114. In some implementations, the memory layer 113 is a composite layer composed of multiple layers, e.g., a tunneling layer, a storage layer (e.g., a “charge trap layer”), and a blocking layer, which can improve performance of the memory block 100. For example, the tunneling layer can enable controlled charge transfer between the semiconducting layer and the memory layer 113 (e.g., due to Fowler-Nordheim tunneling), the storage layer can store trapped charge associated with bits of data, and the blocking layer can inhibit charge leakage out of the semiconductor channel 114.

The present disclosure describes memory blocks in which multiple word lines of the same tier can be conductively connected together. In particular, a memory block (e.g., the example memory block 100 of FIG. 1) can be divided into multiple fingers with interconnected word lines using discontinuous slit structures (SSs). As is described below, discontinuous SSs can also improve structural stability and mitigate defects of a 3D memory architecture when implemented in one or more dummy memory blocks. Furthermore, although the example 3D memory block 100 of FIG. 1 utilizes two staircase structures, in some implementations, a 3D memory block may include no staircase structures, one staircase structure, or more than two staircase structures. For example, in the case of no staircase structures, a 3D memory block can use through-chip vias traversing through a stack of material layers for word line pick-up and fan-out. A 3D memory structure, such as the example described below, can be implemented as a 3D memory block with a single staircase structure. As another example, 3D memory blocks can also use multiple alternating staircase structures (e.g., 3, 4, 5, 6, or more staircase structures) and semiconductor channels to provide multiple stacked data storage structures. All such 3D memory blocks can use the techniques described herein (e.g., SSs and dummy blocks) for structural stability and defect mitigation.

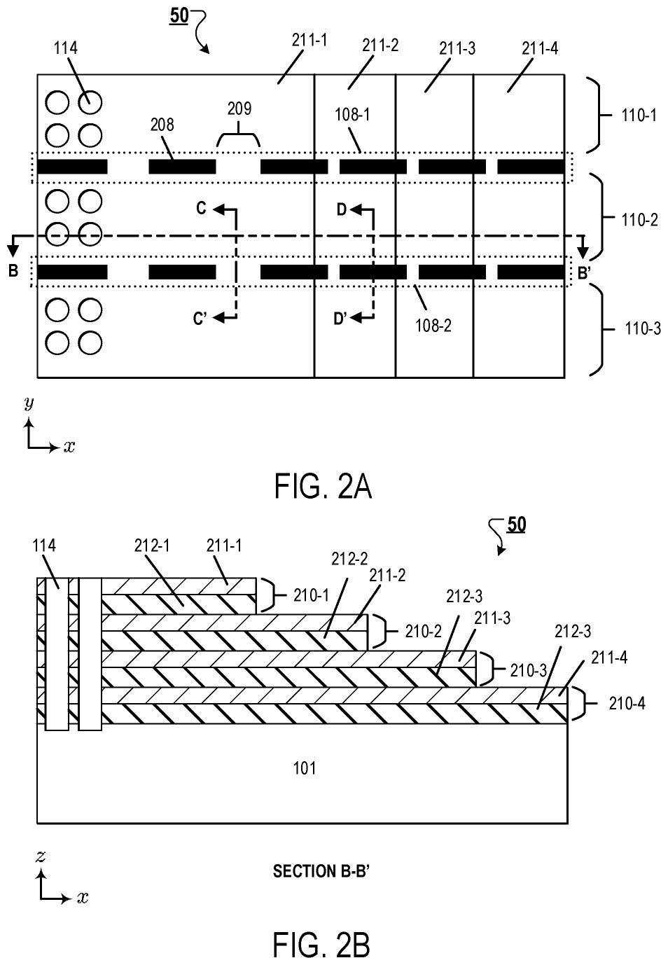

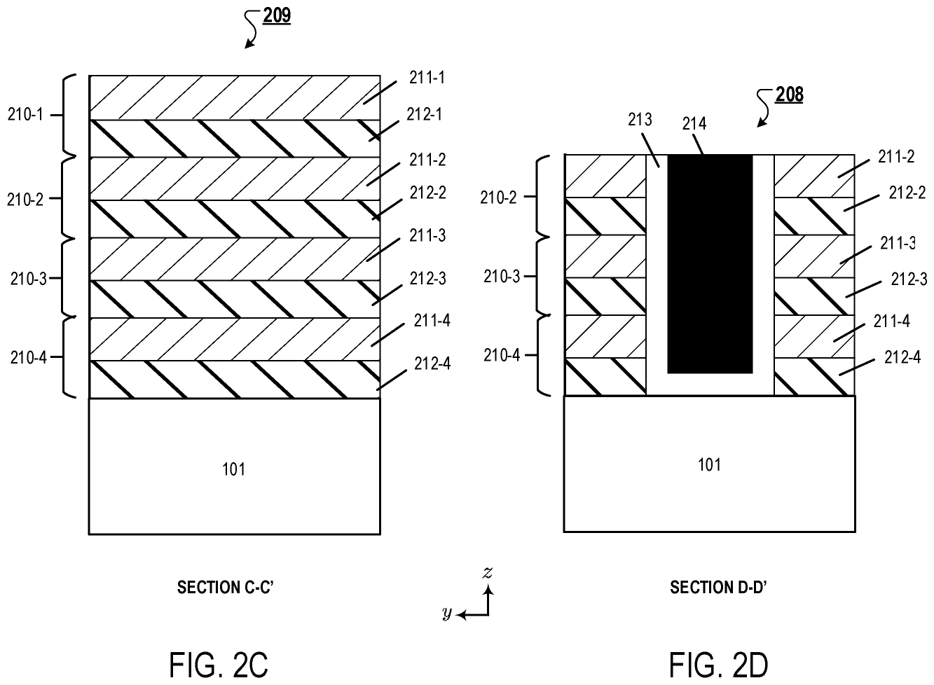

FIGS. 2A-2D show various views of an example 3D memory structure 50 configured to store data. FIG. 2A shows a top view of the example 3D memory structure 50. The memory structure 50 can be employed as an individual memory block, however, the memory structure 50 typically represents half of a memory block (e.g., half of the example 3D memory block 100 of FIG. 1). See FIGS. 3A and 3B for example memory blocks formed by two memory structures. For clarity, various elements such as bit lines, metal contact vias and semiconductor channel layers are omitted from FIGS. 2A-2D to outline the other structural components of the memory structure 50.

Memory structure 50 includes multiple memory strings (in the form of semiconductor channels 114) that provide a stacked data storage structure. The memory structure 50 is divided into multiple fingers 110 by parallel slit structures (SSs) 108, more particularly, discontinuous SSs. The discontinuous SSs 108-1 and 108-2 extend the length of the memory structure 50 horizontally in the x direction. In this way, the semiconductor channels 114 are shared between the fingers 110 and can be accessed by the word lines of each finger 110. Each finger, 110-1, 110-2, and 110-3, corresponds to a stack of word lines (in the form of conductive layers 211) that intersect the semiconductor channels 114 to form memory cell transistors. Note that three fingers 110 are depicted in FIG. 2A as a demonstration but the memory structure 50 can include varying numbers of fingers separated by discontinuous SSs, e.g., 2, 3, 4, 5, 6, or more fingers.

In this context, a discontinuous SS 108 refers to a SS having alternating discrete portions (or slits) 208 and spaces 209. From a top-down view, a discontinuous SS resembles a dashed line segment. Conversely, a continuous SS has a single uninterrupted portion and resembles a solid line segment from a top-down perspective. The discrete portions 208 of the discontinuous SSs 108 electrically isolate the word lines of adjacent fingers 110 while the spaces 209, i.e., regions absent a slit, facilitate electrical connections between word lines of adjacent fingers 110. As mentioned previously, connected word lines of the same tier can share a metal contact via to reduce the total number of metal contact vias and corresponding metal interconnects. Increasing the number of connections in each tier of word lines can also reduce the probability of connection failure.

Different portions 208 and different spaces 209 of a particular discontinuous SS 108 can have differing lengths as desired. In some implementations, the portions 208 can be about 1 micron (μm) to 10 μm in length. The width of the portions 208, in some cases, can be about 0.5 μm to 2 μm. The spaces 209 between the portions 208 can also be about 1 μm to 10 μm in length in some cases. Although the discontinuous SSs 108-1 and 108-2 are depicted with the same pattern of alternating portions 208 and spaces 209, different discontinuous SSs can have different patterns even within the same memory structure 50. For example, different patterns of discontinuous SSs can facilitate different electrical connections between adjacent fingers which can be advantageous in situations involving many fingers, e.g., 4, 5, 6, or more fingers. As is described below, different patterns of discontinuous SSs can also provide improved structural stability, similar to different brick bond patterns used in brick masonry.

FIG. 2B shows a cross-sectional view of the example memory structure 50 along the B-B′ direction. In this implementation, the memory structure 50 employs a staircase structure for word line pick-up and fan-out. However, as mentioned previously, the techniques described herein for defect mitigation can be utilized for memory structures and 3D memory architectures that do not use staircase structures. Section B-B′ is a cross-section through the length of the memory structure 50, intersecting two semiconductor channels 114. As seen in FIG. 2B, the memory structure 50 includes a substrate 101 that supports multiple ascending tiers 210 of layers. The semiconductor channels 114 traverse vertically through the tiers 210 to the substrate 101. The tiers 210 form a staircase structure that can be employed for word line pick-up and fan-out, e.g., by landing metal contact vias on the tiers 210. Each tier 210-1, 210-2, 210-3, and 210-4, includes a respective conductive layer 211 residing on top of a respective insulating layer 212. The conductive layers 211-1, 211-2, 211-3, and 211-4 constitute the word lines of each finger 110. The insulating layers 212-1, 212-2, 212-3, and 212-4 electrically isolate the word lines of different tiers. The discontinuous SSs 108 allow electrical connections to form between adjacent word lines in the same tier. Four tiers 210 of alternating conductive layers 211 and insulating layers 212 are depicted for demonstrative purposes but the memory structure 50 can include significantly more tiers, e.g., 25 tiers or more, 50 tiers or more, 100 tiers or more, 125 tiers or more, 150 tiers more, etc. Moreover, each tier 210 can include more than two layers depending on the implementation. For example, each tier 210 can include a gate dielectric layer sandwiched between the conductive layer 211 and the insulating layer 212. The gate dielectric layers can include high dielectric constant (high-k) materials such as aluminum oxide, hafnium oxide, zirconium oxide, titanium oxide, or combinations thereof.

The substrate 101 can include any suitable semiconducting material and/or insulating material depending on the implementation, e.g., silicon (Si), silicon-germanium (SiGe), silicon carbide (SiC), silicon on insulator (SOI), germanium (Ge), germanium on insulator (GOI), gallium nitride (GaN), gallium arsenide (GaAs), glass, silicon dioxide (SiO₂), silicon nitride (Si₃N₄), silicon oxynitride (SiOₓN_{y}), ceramic, a suitable III-V compound, carbon, or combinations thereof. For instance, if the substrate 101 hosts doped source line regions, substrate 101 can include semiconducting materials to form a well structure. The conductive layers 211 can include any suitable conducting materials, e.g., tungsten (W), cobalt (Co), copper (Cu), aluminum (Al), titanium nitride (TiN), polycrystalline silicon (polysilicon), doped silicon, silicides, or combinations thereof. The insulating layers 212 can include any suitable insulating materials, e.g., silicon dioxide (SiO₂), silicon nitride (Si₃N₄), silicon oxynitride (SiOₓN_{y}), or combinations thereof. The conductive layers 211 and insulating layers 212 can have the same thicknesses or different thicknesses depending on the implementation. In some cases, the bottommost insulating layer in the stack (e.g., insulating layer 212-4) is absent, such that the substrate 101 plays the role of the bottommost insulating layer.

FIG. 2C shows a cross-sectional view of the memory structure 50 along the C-C′ direction. Section C-C′ is a cross-section of a space 209 of a discontinuous SS 108. Here, a space 209 can be characterized as the absence of a slit such that conductive layers 211 of the memory structure 50 are uninterrupted, providing electrical connections between adjacent word lines in the same tier 210. FIG. 2C also illustrates how instabilities and/or defects in the 3D memory structure 50 can arise from various stresses. For example, the stacked tiers 210 are generally stable against compressive stresses in the vertical (z) direction due to the organization of the conductive 211 and insulating 212 layers. However, stresses in the horizontal (x and y) directions can act as shearing stresses that can separate the conductive 211 and insulating 212 layers from one another along their bonding surfaces. In some implementations, the portions 208 can stabilize against these shear stresses similar to reinforcing bars in concrete.

FIG. 2D shows a cross-sectional view of the memory structure 50 along the D-D′ direction. Section D-D′ is a cross-section of a portion 208 of a discontinuous SS 108 depicting the vertical slit structures of SSs. The portion 208 corresponds to a slit in the memory structure 50 though the stack such that conductive layers 211 are interrupted, isolating electrical pathways on either side of the portion 208. The portion 208 is lined with an insulating material 213 and filled with a filling material 214. In some implementations, portions 208 of SSs are partially filled or entirely filled with the insulating material 213. The insulating material 213 can include any of the materials described above for the insulating layers 212. The filling material 214 can include insulating or conducting materials. For example, in some implementations, the filling material 214 can be a conducting material (e.g., any of the materials described above for the conductive layers 211) to interact with source lines in the substrate 101.

A set of SSs, including both continuous SSs and/or discontinuous SSs, can be formed by various methods. An example process to form SSs in a memory structure, a memory block and/or an array of memory blocks is described to realize the technical effect of SSs. The example process is as follows:
1. Provide an alternating stack of insulating layers 212 and sacrificial layers. For example, the insulating layers 212 and the sacrificial layers can be deposited on the substrate 101 in an alternating fashion. In some implementations, the sacrificial layers are composed of silicon nitride (Si₃N₄).
2. Etch trenches (corresponding to portions of the SSs) through the stack. For example, if one or more of the SSs are discontinuous SSs, a series of trenches can be etched for each discontinuous SS. If one or more of the SSs are continuous SSs, a continuous trench can be etched for each continuous SS.
3. Remove the sacrificial layers and deposit conductive layers 211 in the cavities formed by the sacrificial layers, thereby generating an alternating stack of conductive layers 211 and insulating layers 212.
4. Recess the conductive layers 211 to remove any excess conductive material in the etched trenches.
5. Fill the trenches in the stack with the insulating material 213.
6. Optionally, etch the insulating material 213 to form a trench in the insulating material 213, and fill the trenches in the insulating material 213 with the filling material 214.
7. Alternatively to steps 5 and 6, line the trenches in the stack with the insulating material 213, and fill the lined trenches with the filling material 214.

When performing the foregoing process, the insulating layers 212, the sacrificial layers, the conductive layers 211, the insulating material 213 and the filling material 214 can be deposited with any suitable deposition method, e.g., chemical vapor deposition (CVD), physical vapor deposition (PVD), plasma-enhanced CVD (PECVD), low pressure CVD (LPCVD), metal-organic CVD (MOCVD), sputtering, atomic layer deposition (ALD), or combinations thereof. Various other components, such as semiconductor channels 114 and bit lines, can be formed before, after, or in between (at least some of) the steps of the aforementioned process.

FIGS. 3A and 3B are top views depicting examples of memory blocks 100A and 100B formed by two memory structures 50-1 and 50-2, e.g., two of the memory structures 50 shown in FIGS. 2A-2D. In general, the memory blocks 100A and 100B include one or more core array regions 51 and one or more staircase structure regions 52. A core array region 51 includes semiconductor channels 114 (e.g., memory strings) that constitute a stacked data storage structure. A staircase structure region 52 includes staircase structures where, for example, metal contact vias can be landed on different tiers for word line pick-up and fan-out. The memory blocks 100A and 100B are divided into multiple fingers 110-1, 110-2 and 110-3 by discontinuous SSs 108-1 and 108-2 which accommodate electrical connections between word lines of the same tier.

Referring to FIG. 3A, the memory block 100A includes two core array regions 51-1 and 51-2 with a staircase structure region 52 between them. In this case, the tiers of the staircase structures 52 ascend from the center of the memory block 100A towards the core array regions 51-1 and 51-2 at its opposing sides. Conversely, in reference to FIG. 3B, the memory block 100B includes two staircase structure regions 52-1 and 52-2 with a core array region 51 between them. Memory block 100B has a similar configuration as the memory block 100 shown in FIG. 1. In this case, the tiers of the staircase structures 52-1 ascend from the opposing sides of the memory block 100B towards the core array region 51 at its center.

The memory blocks 100A and 100B are example configurations of 3D memory blocks that can be implemented in a 3D memory device to provide a desired data storage capacity. However, the 3D memory devices described herein are not limited to such. A 3D memory block can have more (or fewer) core array regions 51 and staircase structure regions 52 than those outlined above in FIGS. 3A and 3B. For example, a memory block can have multiple alternating core array regions 51 and staircase structure regions 52 formed by multiple memory structures 50 (e.g., 3, 4, 5, 6, or more memory structures). In some cases, a 3D memory block may have no staircase structure regions and uses different structures for word line pick-up and fan-out, e.g., word line pick-up structures and/or through-chip vias traversing through a stack of material layers. The methods described below for stabilizing 3D memory architectures can be implemented for all such memory blocks.

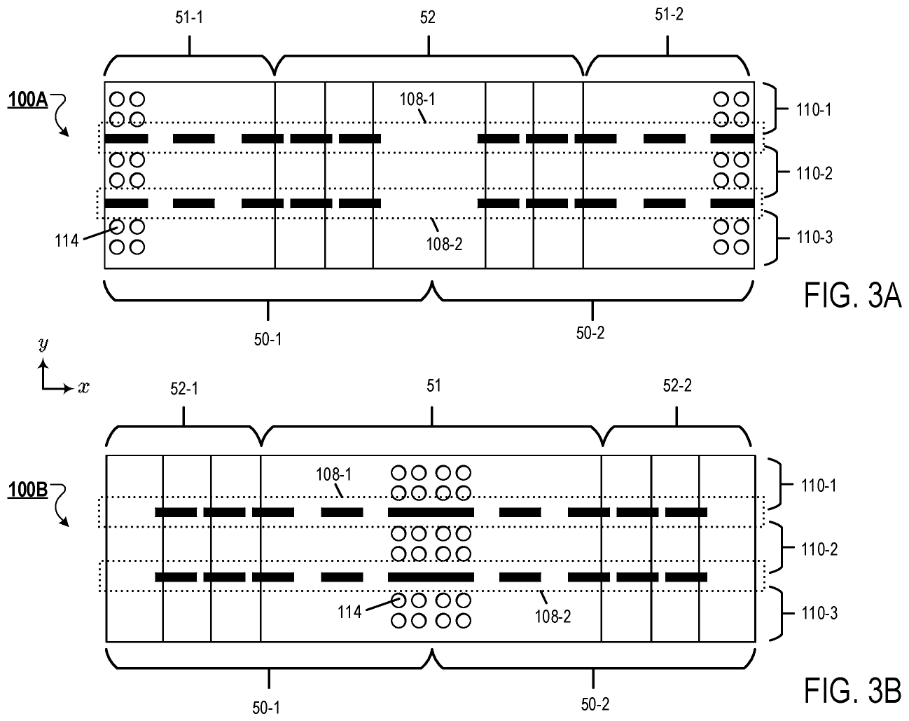

FIG. 4 is a top view showing an example of a semiconductor die 30 on which multiple 3D memory devices 10-1 . . . 15 are fabricated. The 3D memory devices 10 can be separated and employed in an integrated circuit and/or an electronic device for data storage and retrieval, e.g., in combination with a memory controller. The specific number of 3D memory devices 10 fabricated on the die 30 can vary and depends on the particular manufacturing process implemented. Large-scale fabrication techniques can produce large quantities of 3D memory devices 10 in unison. Nevertheless, horizontal edge stresses 31 between adjacent 3D memory devices 10 can be significant and can increase the prevalence of defects in the 3D memory devices 10 during fabrication. For example, the edge stresses 31 can cause shearing stresses in the 3D memory devices 10 which 3D memory architectures are generally susceptible to.

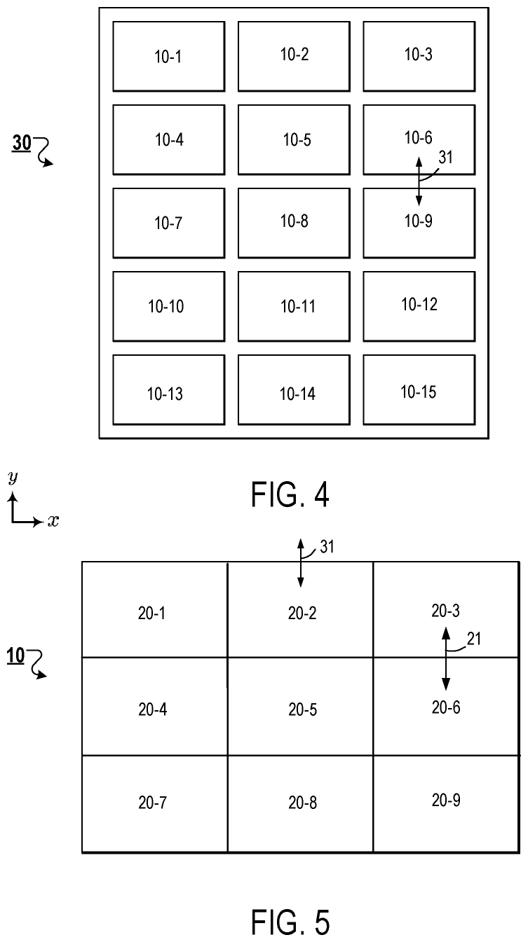

FIG. 5 is a top view showing an example of a 3D memory device 10 that includes multiple memory planes 20-1 . . . 9. A memory plane 20 generally provides a certain data storage capacity, e.g., by organizing multiple memory blocks in a linear array. Although nine memory planes 20 with equivalent sizes are shown in FIG. 5, the 3D memory device 10 can include any number of memory planes, e.g., 1, 2, 3, 4, 5, 6, 7, 8, 9, 10, 11, 12, 13, 14, 15 or more memory planes. Each memory plane 20 may have different sizes, although uniform sizes are generally desirable from a fabrication and application standpoint. That being said, similar to edge stresses 31 between adjacent 3D memory devices 10, edge stresses 21 between adjacent memory planes 20 can increase the prevalence of defects in the memory planes 20-1 . . . 9. The edge stresses 21 and 31 can arise from various effects, e.g., imperfect deposition of material layers, imperfect etching of tiers and semiconductor channels, etc. The edge stresses 21 and 31 generally increase with increasing numbers of layers and/or increasing height of the 3D architecture. For example, due to increasing loads, increased number of bonding surfaces and/or imperfect layer depositions, the 3D architecture may tend to buckle, which can cause significant stress near the edges of a memory plane 20.

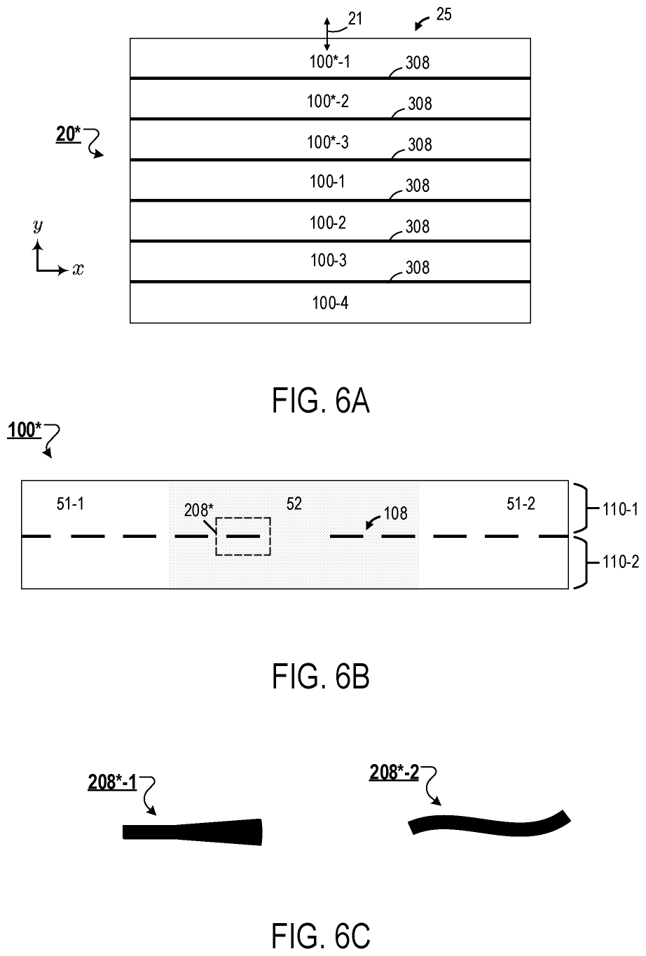

FIG. 6A is a top view showing an example of a defective memory plane 20* resulting from edge stresses 21 and/or 31. The defective memory plane 20* includes a linear array of memory blocks that are separated by continuous gate lines slits (SSs) 308 into individual units. The continuous SSs 308 can also electrically isolate adjacent memory blocks in the array, e.g., by lining or filing the SSs 308 with an insulating material. The memory blocks can share a common substrate such that the memory blocks are fabricated on the memory plane 20* in unison from a stack of material layers deposited on the substrate. For example, the stack of material layers can be etched and various other materials can be deposited to form the memory blocks and different components of the memory blocks, e.g., SSs, semiconductor channels, bit lines, word lines, metal contact vias, staircase structures, etc. The memory blocks may also mutually share some components (e.g., bit lines) for purposes such as memory cell row selections.

The linear array includes multiple defective memory blocks 100*-1 . . . 3 near an edge 25 of the memory plane 20 and multiple functional memory blocks 100-1 . . . 4. In general, the edge stresses 21 and 31 cause a majority defects in memory blocks 100* near the edge 25 of the memory plane 20. Defective memory blocks 100* with significant defects and/or dimensional variations are usually sacrificed and cannot be utilized for data storage. This limits the overall storage capacity of the memory plane 20*. Hence, it is desirable to minimize the number defective memory blocks 100* in a memory plane.

FIG. 6B is a top view showing an example of a defective memory block 100* with two fingers 110-1 and 110-2 separated by a discontinuous SS 108. Components such as semiconductor channels, bit lines, metal contact vias, etc. are omitted for clarity. In this case, the defective memory block 100* has a configuration resembling memory block 100A with a staircase structure region 52 between two core array regions 51-1 and 51-2. The edge stresses 21 and 31 can result in significant defects and/or variations in one or more portions 208* of a discontinuous SS 108, among other deficiencies. Since electronic devices can be sensitive to feature sizes and uniformity, the defects and/or variations can cause unpredictable and/or degraded performance of the memory block 100*. For example, defective portions 208* can alter the conductive properties between adjacent fingers 110 which can increase the probability of word line connection failures. Connection failures can increase data programming errors (e.g., false programming of one or more memory cells) and/or render the memory block 100* inoperable.

FIG. 6C is a top view showing examples of defective portions 208* of a discontinuous SS resulting from edge stresses 21 and/or 31. Defective portion 208*-1 has a tapered profile such that the width of the portion 208*-1 varies across its length. Defective portion 208*-2 has a curved profile such that the length of the portion 208*-2 has an “S”-like shape. Defective portions 208* can vary in numerous other ways, all of which can be detrimental to the performance of a memory block, e.g., by causing word line connection failures.

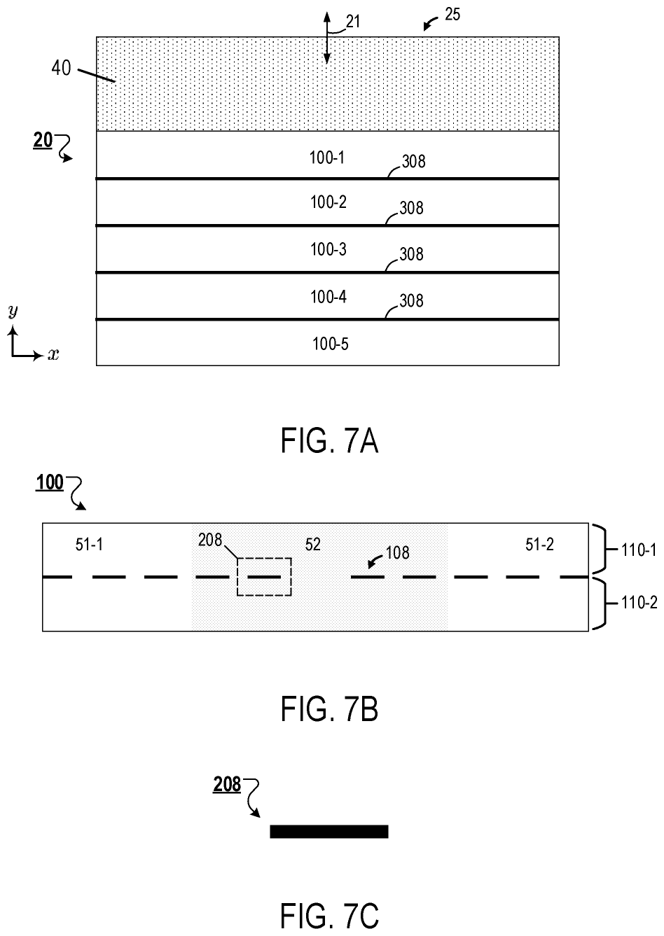

FIG. 7A is a top view showing an example of a memory plane 20 including a dummy region 40. The dummy region 40 is adjacent to an edge 25 of the memory plane 20 and absorbs a majority of the edge stress 21. The memory plane 20 includes a linear array of memory blocks 100-1 . . . 5 that are separated and electrically isolated from one another by continuous SSs 308. The dummy region 40 is situated between the edge 25 and the memory blocks 100-1 . . . 5 to stabilize the memory plane 20 and mitigate defects in the memory blocks 100-1 . . . 5. In general, the dummy region 40 includes one or more dummy memory blocks, i.e., memory blocks that are intentionally sacrificed, to preserve and increase the number of functional memory blocks 100-1 . . . 5 in the memory plane 20. For example, as a demonstration, memory plane 20 includes five functional memory blocks compared to four in defective memory plane 20*. Accordingly, memory plane 20 accommodates increased data storage capacity. Appropriately optimized dummy regions 40 can see gains in both the number and height of functional memory blocks 100, thereby increasing both storage density and overall capacity. As is described below, the dummy blocks in the dummy region 40 are fabricated with different patterns of discontinuous SSs that provide improved structural stability and reduced defect accumulation in the memory blocks 100.

As seen in FIG. 7A, the memory plane 20 includes a single dummy region 40 adjacent to the top edge 25. However, the dummy region 40 can be located in any region of the memory plane 20. Alternatively or in addition, multiple dummy regions can be implemented into the memory plane 20. For example, a dummy region can be adjacent the top edge 25, a bottom edge, or both. A dummy region can also be located interior to the memory plane 20, between different memory blocks 100. In some cases, a dummy region in the interior of the memory plane 20 can mitigate deformations due to internal stresses. In general, the memory plane 20 can include one or more dummy regions, each dummy region including one or more dummy blocks, situated anywhere within the array to improve structural stability

FIG. 7B is a top view showing an example of a (non-defective) memory block 100 included in the memory plane 20 of FIG. 7A. The memory block 100 includes a staircase structure region 52 between two core array regions 51-1 and 51-2 and a discontinuous SS 108 dividing the memory block 100 into two fingers 110-1 and 110-2. Due to stabilization from the dummy region 40, the memory block 100 includes only a few, or no, defects. FIG. 7C is a top view showing an example of a portion 208 of the discontinuous SS 108. As can be seen in FIG. 7C, the portion 208 is free from defects and/or variations, having a uniform width along its length. As mentioned previously, this uniformity can allow consistent operation of the memory block 100, e.g., by ensuring electrical connections between adjacent word lines are less prone to failure.

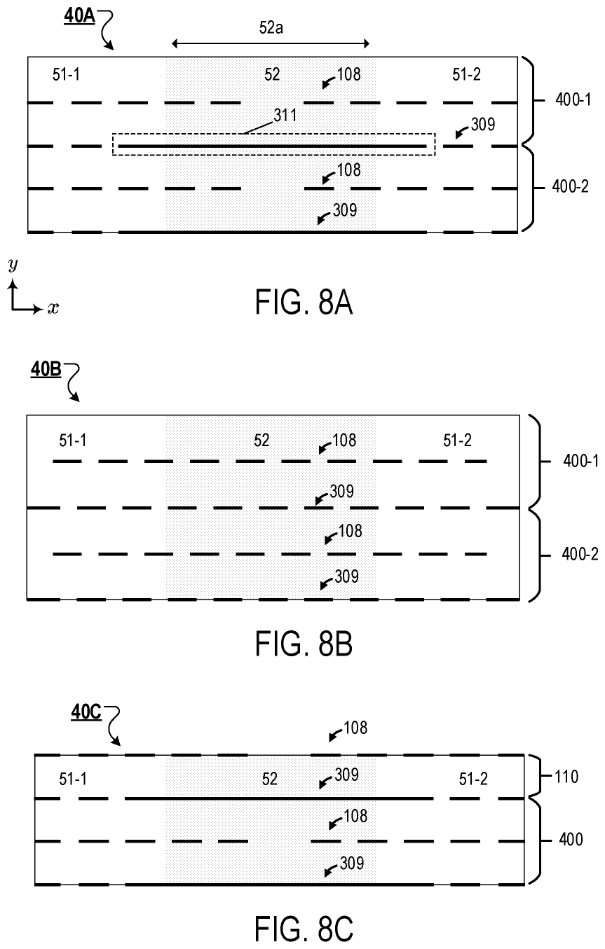

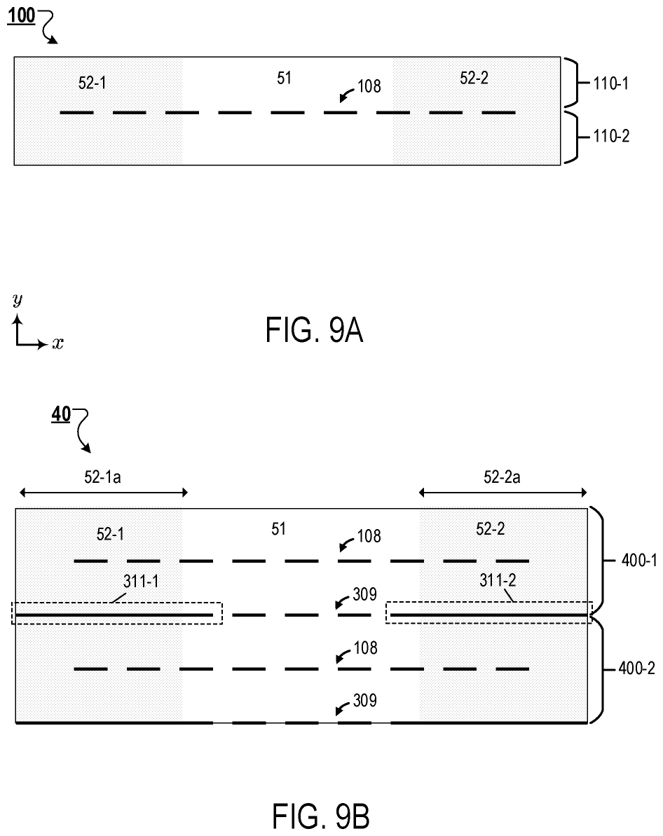

FIGS. 8A-8C are top views depicting examples of dummy regions 40A-40C that can be implemented in a memory plane for stabilization. In this case, the dummy regions 40A-40C have a staircase structure region 52 between two core array regions 51-1 and 51-2, but other configurations are also possible, e.g., a core array region between two staircase structure regions as observed in FIG. 9B, among other configurations mentioned previously.

Referring to FIG. 8A, the dummy region 40A includes two dummy memory blocks 400-1 and 400-2 corresponding to two intentionally sacrificed memory blocks. The dummy blocks 400-1 and 400-2 are separated by discontinuous SSs 309 of a second type and are divided into fingers by discontinuous SSs 108 of a first type. In this case, dummy blocks 400 in the dummy region 40A can be fabricated by interrupting a continuous SS between adjacent memory blocks. That is, discontinuous SSs 309 of the second type can be fabricated in place of continuous SSs in the dummy region 40A. The alternating pattern of discontinuous SSs 108 and 309 provides improved structural stability to a memory plane that would otherwise be limited by the presence of a continuous SS in the dummy region 40A. Moreover, the discontinuous SSs 108 and 309 can be fabricated to support different regions of a memory plane. For example, discontinuous SS 309 of the second type includes a long portion 311 at its center, substantially extending a length 52a of the staircase structure region 52. In some implementations, the long portion 311 that has a length greater than the length 52a of the staircase structure region 52. Since the ascending tiers of staircase structures can be prone to instabilities, the long portion 311 can provide better support than a series of short portions.

FIG. 8B shows another example of a dummy region 40B including two dummy blocks 400-1 and 400-2. The dummy blocks 400 are sectioned by alternating discontinuous SSs of a first type 108 and a second type 309, but with patterns different from dummy region 40A. In general, since a dummy region is not utilized for data storage, any pattern of one or more discontinuous SSs can be implemented. Some patterns may be preferable to others depending on the relative structure of the memory blocks in a memory plane. For example, the alternating discontinuous SSs 108 and 309 shown in FIG. 8B resemble a running bond brick laying pattern which are sometimes utilized for their strength and stability.

FIG. 8C shows another example of a dummy region 40C that is a variation of the dummy region 40A in FIG. 8A. Here, dummy region 40C includes one and a half dummy blocks, e.g., a dummy block 400 and a finger 110. Again, since a dummy region is not utilized for data storage, any number of dummy blocks can be utilized, even fractions of a dummy block.

FIGS. 9A and 9B are top views depicting examples of a memory block 100 and a dummy region 40 with a core array region 51 between two staircase structure regions 52-1 and 52-2, similar to the configuration of memory block 100B of FIG. 3B. One or more of the memory block 100 and the dummy region 40 can be implemented in a memory plane for data storage and structural stability. As can be seen in FIGS. 9A and 9B, different patterns of discontinuous SSs can be utilized for different 3D architectures, e.g., 3D architectures with different arrangements of core array regions and staircase structure regions. In this implementation, discontinuous SSs of a first type 108 divide the memory block 100 and the dummy region into fingers. Discontinuous SSs 309 of a second type separate dummy blocks 400-1 and 400-2 from one another and can be fabricated in place of continuous SSs in the dummy region 40A. Discontinuous SS 309 of the second type also includes two long portions 311-1 and 311-2 at its ends, substantially extending the lengths 52-1a and 52-2a of the staircase structure regions 52-1 and 52-2. In some implementations, the two long portions 311-1 and 311-2 have lengths greater than the lengths 52-1a and 52-2a of the staircase structure regions 52-1 and 52-2.

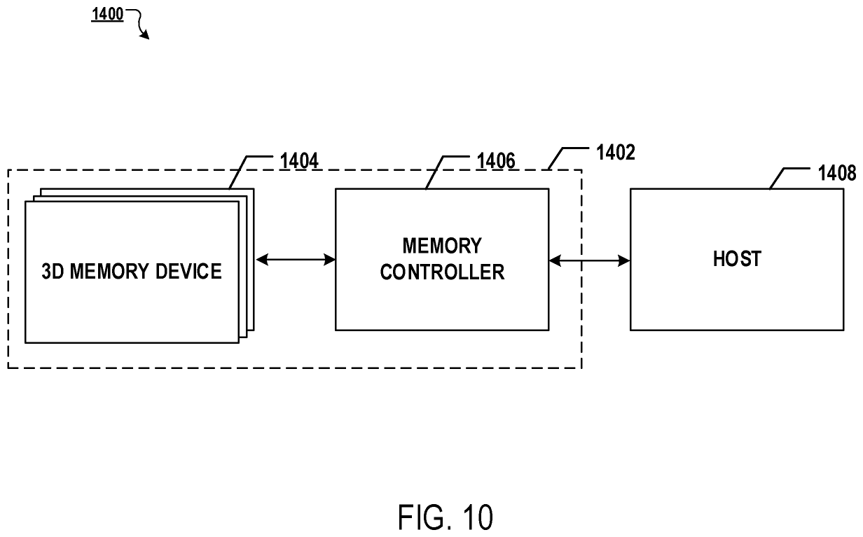

FIG. 10 illustrates a schematic diagram of an example system 1400 including one or more 3D memory devices. System 1400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, system 1400 can include a host 1408 and a memory system 1402 having one or more 3D memory devices 1404 and a memory controller 1406. Host 1408 can be a processor of an electronic device, such as a central processing unit (CPU), or a system-on-chip (SoC), such as an application processor (AP). Host 1408 can be configured to send or receive data to or from 3D memory devices 1404.

The 3D memory devices 1404 can be any combination of 3D memory devices disclosed herein, such as NAND Flash memory devices, NOR Flash memory devices, phase change memory (PCM) devices, resistive memory devices, RAM memory devices, DRAM memory devices, RRAM memory devices, magnetic memory devices, spin transfer torque (STT) memory devices, among others. All such memory devices can be fabricated with superior stability and/or reduced defects using the disclosed methods (e.g., appropriately patterned SSs and one or more dummy memory blocks). In some implementations, each 3D memory device 1404 includes a NAND Flash memory. Memory controller 1406 (a.k.a., a controller circuit) is coupled to 3D memory device 1404 and host 1408 and is configured to control 3D memory device 1404. For example, the controller circuit may be configured to operate the memory cells of the 3D memory devices 1404 via word lines and/or bit lines. Memory controller 1406 can manage the data stored in 3D memory device 1404 and communicate with host 1408.

According to one aspect of the present disclosure, a three-dimensional (3D) memory device includes a memory plane, where the memory plane includes a first edge and an array of blocks. The array of blocks includes a plurality of memory blocks configured to store data, where the plurality of memory blocks are separated by continuous slit structures, and a first dummy region between the first edge and the plurality of memory blocks. The first dummy region includes alternating first slit structures and second slit structures, where the first slit structures and the second slit structures are discontinuous slit structures.

In some implementations, the first dummy region includes one to four dummy blocks.

In some implementations, each dummy block includes two of the first slit structures, and one or more of the second slit structures are between the two first slit structures.

In some implementations, the memory plane includes a second edge opposite the first edge and a second dummy region between the second edge and the plurality of memory blocks, the second dummy region including alternating first slit structures and second slit structures.

In some implementations, each memory block is divided into a plurality of fingers by discontinuous slit structures.

In some implementations, the array of blocks includes a staircase structure region between two core array regions.

In some implementations, each first slit structure includes a slit extending across the staircase structure region, and the slit has a length at least greater than a length of the staircase structure region.

In some implementations, the array of blocks includes a core array region between two staircase structure regions.

In some implementations, each block includes alternating layers of an oxide and layers of tungsten, and for each discontinuous slit structure including alternating slits and spaces, each space includes the alternating layers of the oxide and layers of tungsten.

In some implementations, each slit structure includes an insulating material.

In some implementations, the insulating material lines each slit structure.

In some implementations, the insulating material includes at least one of an oxide, carbon, or polysilicon.

In some implementations, each slit structure is filled with a filling material.

In some implementations, the filling material includes a conductive material.

In some implementations, each slit of each discontinuous slit structure has a length in a range from 1 micron to 10 microns.

In some implementations, the slits of each discontinuous slit structure are 1 micron to 10 microns apart from one another.

In some implementations, the continuous slit structures electrically isolate the plurality of memory blocks.

According to another aspect of the present disclosure, a system includes a three-dimensional (3D) memory device and a memory controller electrically connected to the 3D memory device, where the memory controller is configured to manage data to and from the 3D memory device. The 3D memory device includes a memory plane, where the memory plane includes a first edge and an array of blocks. The array of blocks includes a plurality of memory blocks configured to store data, where the plurality of memory blocks are separated by continuous slit structures, and a first dummy region between the first edge and the plurality of memory blocks. The first dummy region includes alternating first slit structures and second slit structures, where the first slit structures and the second slit structures are discontinuous slit structures.

According to still another aspect of the present disclosure, a three-dimensional (3D) memory device includes a memory plane, where the memory plane includes a first edge and an array of blocks. The array of blocks includes a plurality of memory blocks configured to store data, where the plurality of memory blocks are separated by continuous slit structures, and one or more dummy blocks between the first edge and the plurality of memory blocks. Each dummy block includes a first slit structure separating adjacent blocks and one or more second slit structures dividing the dummy block into a plurality of fingers, where the first slit structure and the one or more second slit structures are discontinuous slit structures.

In some implementations, the array of blocks includes one to four dummy blocks.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents. Accordingly, other implementations are within the scope of the claims.

What is claimed is:

1. A three-dimensional (3D) memory device comprising a memory plane, wherein the memory plane comprises:
a first edge; and
an array of blocks comprising:
a plurality of memory blocks configured to store data, wherein the plurality of memory blocks are separated by continuous slit structures; and
a first dummy region between the first edge and the plurality of memory blocks, the first dummy region comprising alternating first slit structures and second slit structures, wherein the first slit structures and the second slit structures are discontinuous slit structures.

2. The 3D memory device of claim 1, wherein the first dummy region comprises one to four dummy blocks.

3. The 3D memory device of claim 2, wherein each dummy block comprises two of the first slit structures, and wherein one or more of the second slit structures are between the two first slit structures.

4. The 3D memory device of claim 1, wherein the memory plane comprises:
a second edge opposite the first edge; and
a second dummy region between the second edge and the plurality of memory blocks, the second dummy region comprising alternating first slit structures and second slit structures.

5. The 3D memory device of claim 1, wherein each memory block is divided into a plurality of fingers by one or more discontinuous slit structures.

6. The 3D memory device of claim 1, wherein the array of blocks comprises a staircase structure region between two core array regions.

7. The 3D memory device of claim 6, wherein each first slit structure comprises a slit extending across the staircase structure region, and wherein the slit has a length at least greater than a length of the staircase structure region.

8. The 3D memory device of claim 1, wherein the array of blocks comprises a core array region between two staircase structure regions.

9. The 3D memory device of claim 1, wherein each block comprises alternating layers of an oxide and layers of tungsten, and wherein, for each discontinuous gate slit structure comprising alternating slits and spaces, each space comprises the alternating layers of the oxide and layers of tungsten.

10. The 3D memory device of claim 1, wherein each slit structure comprises an insulating material.

11. The 3D memory device of claim 10, wherein the insulating material lines each slit structure.

12. The 3D memory device of claim 10, wherein the insulating material comprises at least one of an oxide, carbon, or polysilicon.

13. The 3D memory device of claim 11, wherein each slit structure is filled with a filling material.

14. The 3D memory device of claim 13, wherein the filling material comprises a conductive material.

15. The 3D memory device of claim 1, wherein each slit of each discontinuous slit structure has a length in a range from 1 micron to 10 microns.

16. The 3D memory device of claim 1, wherein slits of each discontinuous slit structure are 1 micron to 10 microns apart from one another.

17. The 3D memory device of claim 1, wherein the continuous slit structures electrically isolate the plurality of memory blocks.

18. A system, comprising:
a three-dimensional (3D) memory device comprising a memory plane, wherein the memory plane comprises:
a first edge; and
an array of blocks comprising:
a plurality of memory blocks configured to store data, wherein the plurality of memory blocks are separated by continuous slit structures; and
a first dummy region between the first edge and the plurality of memory blocks, the first dummy region comprising alternating first slit structures and second slit structures, wherein the first slit structures and the second slit structures are discontinuous slit structures; and
a memory controller electrically connected to the 3D memory device, wherein the memory controller is configured to manage data to and from the 3D memory device.

19. A three-dimensional (3D) memory device comprising a memory plane, wherein the memory plane comprises:
a first edge; and
an array of blocks comprising:
a plurality of memory blocks configured to store data, wherein the memory blocks are separated by continuous slit structures; and
one or more dummy blocks between the first edge and the plurality of memory blocks, each dummy block comprising a first slit structure separating adjacent blocks and one or more second slit structures dividing the dummy block into a plurality of fingers, wherein the first slit structure and the one or more second slit structures are discontinuous slit structures.

20. The 3D memory device of claim 19, wherein the array of blocks comprises one to four dummy blocks.
